(19) United States
(12) Patent Application Publication
(10) Pub. No.: US 2006/0112879 A1
(43) Pub. Date: Jun. 1, 2006

(54) Plasma processing apparatus

(76) Inventors: Jin Seok Lee, Seoul (KR); Jung Wook Kim, Seongnam-Si (KR); Dong Seok Baek, Suwon-Si (KR)

Correspondence Address: STANZIONE & KIM, LLP, 919 18TH STREET, N.W., SUITE 440, WASHINGTON, DC, 20006, US

(21) Appl. No.: 11/144,735

(22) Filed: Jun. 6, 2005

(30) Foreign Application Priority Data
Nov. 26, 2004 (KR) 2004-98198

(51) Int. Cl. C23C 16/00; B05C 11/00

(52) U.S. Cl. 118/723 R; 118/715; 118/713

(57) ABSTRACT

A plasma processing apparatus includes a view port to ensure ground continuity on a wall of a process chamber, so that uniformity of a process is enhanced. The view port of plasma processing apparatus includes a ground cover electrically connected to a wall of a chamber. The ground cover contacts the wall of the chamber to form contact surfaces, and the contact surfaces of the ground cover are constituted by bare surfaces. Accordingly, the ground continuity is ensured around the view port, thereby providing uniformity of an electric field and plasma within the chamber.

### CROSS-REFERENCE TO RELATED APPLICATIONS

This application claims the benefit of Korean Patent Application No. 2004-98198, filed on Nov. 26, 2004 in the Korean Intellectual Property Office, the disclosure of which is incorporated herein by reference.

### BACKGROUND OF THE INVENTION

1. Field of the Invention

The present general inventive concept relates to a plasma processing apparatus, and more particularly, to a plasma processing apparatus, which has a view port to allow observation of plasma state within a chamber.

2. Description of the Related Art

In semiconductor processing, plasma has been widely used for various applications, such as plasma ion etching, plasma physical vapor deposition (PVD), plasma chemical vapor deposition (CVD), plasma ashing, plasma chamber cleaning, and the like. Plasma processing equipment generally comprises a process chamber, a substrate support, a reactant gas supply, a radio frequency (RF) power supply, an exhaust pump, and the like.

In a plasma process, completion of the process is detected by measuring variation in plasma emission spectrum. For this purpose, the process chamber is provided with a view port to allow observation of an emission state of plasmas.

A conventional construction of a view port of the plasma processing equipment is disclosed in Korean Patent Laid-open Publication No. 2001-0072886. In this publication, the plasma processing equipment comprises a process chamber to receive a wafer in an inner space thereof for plasma generation, a susceptor constituting a lower electrode, a showerhead constituting an upper electrode, and the like. The bottom of the process chamber is connected to an exhaust pipe to maintain the inner space of the process chamber in a vacuum state of a predetermined level. The susceptor is connected to an RF power supply to form a high frequency electric field between the susceptor and the showerhead, thereby creating plasmas from reactant gases within the process chamber.

In the meantime, a shield member having a smaller diameter than that of the process chamber is equipped on a wall of the process chamber, and a window device, that is, the view port is disposed on the wall of the process chamber and the shield member to detect the plasma state. The window device comprises a window plate made of quartz, an optical guide made of aluminum and inserted into the shield member, and a cover plate made of sapphire and attached to the optical guide, in which the optical guide has an anodized surface.

Even though the wall of the process chamber is earth grounded, the insulating window plate is inserted into the wall of the process chamber, so that ground continuity is broken on the wall of the process chamber where the window plate is inserted thereto. This causes non-uniform distribution of the electric field, and non-uniform plasma formed within the process chamber, resulting in a non-uniform process on the wafer.

In this plasma processing equipment, the window plate, the optical guide, and the cover plate are inserted into the wall of the process chamber. However, even with this construction, since the window plate and the cover plate are made of the insulating material, and the surface of the aluminum optical guide has an insulating film formed thereon by the anodizing treatment, ground continuity with the wall of the process chamber is still not assured.

### SUMMARY OF THE INVENTION

The present general inventive concept provides a plasma processing apparatus, which comprises a process chamber designed to ensure ground continuity on a wall of the processing chamber, thereby enhancing uniformity of a process.

Additional aspects and/or advantages of the invention will be set forth in part in the description which follows and, in part, will be obvious from the description, or may be learned by practice of the invention.

These and/or other aspects and advantages of the present general inventive concept may be achieved by providing a plasma processing apparatus comprising an earth-grounded chamber; a gas supply and a radio-frequency (RF) power supply to create plasma within the chamber, a view port formed through a chamber wall of the chamber to allow observation of the interior of the chamber, a transparent window disposed in the view port to transmit light created from the plasma therethrough, and a ground cover disposed in the view port in an earth grounded state to maintain ground continuity around the transparent window.

The ground cover may contact the chamber wall to form a contact surface, and the contact surface may be a bare surface to contact the view port to be in the earth grounded state.

The ground cover may have a plurality of holes formed therethrough to allow the light emitted from the plasma to pass through the ground cover.

The ground cover may be adapted to cover a front side of the transparent window facing the interior of the chamber.

The view port may be further provided with a frame to fix the transparent window to the view port.

The view port may be further provided with at least one O-ring to maintain air-tightness.

The view port may be further provided with a shielding net to prevent leakage of an RF electric field generated from the interior of the chamber, and an ultraviolet (UV) filter to shield against ultraviolet rays emitted by the plasma.

### BRIEF DESCRIPTION OF THE DRAWINGS

These and/or other aspects and advantages of the present general inventive concept will become apparent and more readily appreciated from the following description of the embodiments, taken in conjunction with the accompanying drawings, of which:

FIG. 1 is a schematic diagram illustrating a plasma processing apparatus according to an embodiment of the present general inventive concept;

FIG. 2 is an enlarged view illustrating a portion A of the plasma processing apparatus of FIG. 1;

FIG. 3 is an exploded perspective view illustrating a view port of the plasma processing apparatus of FIG. 1; and

FIGS. 4A and 4B are topographs illustrating distribution of an etch rate on a wafer subjected to an etching process using conventional plasma processing equipment and the plasma processing apparatus of FIG. 1, respectively.

### DETAILED DESCRIPTION OF THE PREFERRED EMBODIMENTS

Reference will now be made in detail to the embodiments of the present general inventive concept, examples of which are illustrated in the accompanying drawings. The embodiments are described below to explain the present general inventive concept by referring to the figures.

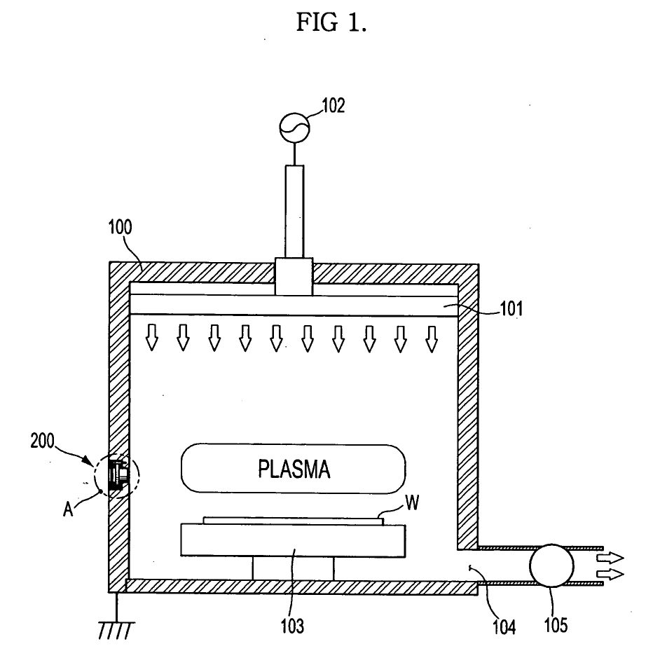

Referring to FIG. 1, a plasma processing apparatus according to the present general inventive concept comprises a chamber 100 to allow plasma to be created therein while maintaining an inside of the chamber 100 in a vacuum state of a predetermined level during a process, a reactant gas supply 101 to supply reactant gases to the chamber 100, an RF power supply 102 to create the plasma from the reactant gases within the chamber 100, and a substrate support 103 to support a substrate W within the chamber 100.

An exhaust port 104 is formed at one side of the chamber 100, and is in communication with a vacuum pump 105, which discharges the reactant gases within the chamber 100 during the process to maintain the vacuum state of the predetermined level within the chamber 100.

The gas supply 101 has a typical showerhead shape and is connected to the RF power supply 102 to constitute an upper electrode, and the substrate support 103 is provided with a lower electrode (now shown), so that an RF electric field is created between the upper electrode and the lower electrode.

Meanwhile, the chamber 100 is generally made of an electrically conductive material, such as aluminum, and is earth grounded. The chamber 100 has an opening and a view port 200 formed through one wall thereof and disposed in the opening thereof to allow observation of a state of the plasma created within the chamber 100. Light generated from the plasma during the process is emitted to an outside through the view port 200, so that a user of the plasma processing apparatus can determine regularity and progress of the process by detecting the light by the naked eye or a measuring device.

The detailed constructions of the chamber 100, the gas supply 101, the RF power supply 102, the substrate support 103, and the like as described above can be changed according to a type of the process, and these constructions are disclosed only as an example in this embodiment. The construction of the view port 200 will be described in detail as follows.

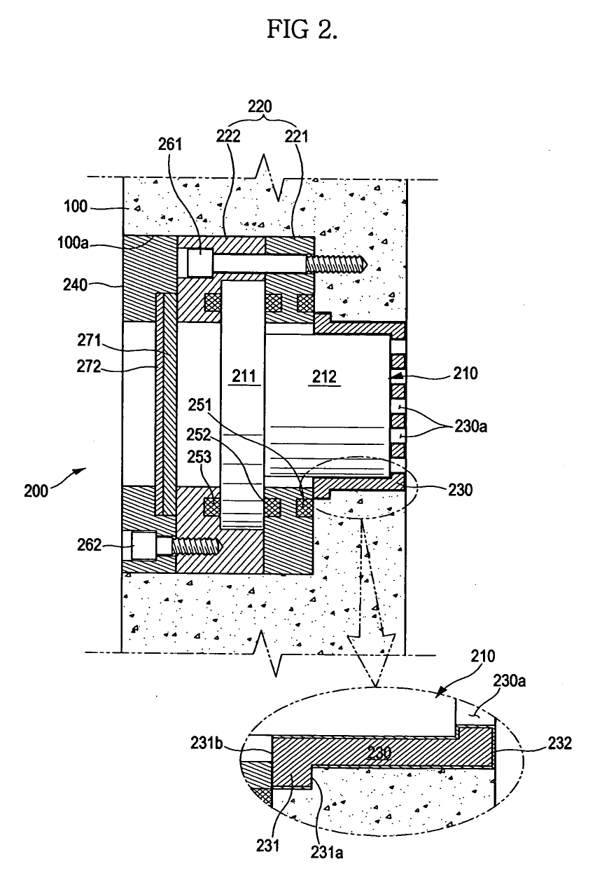

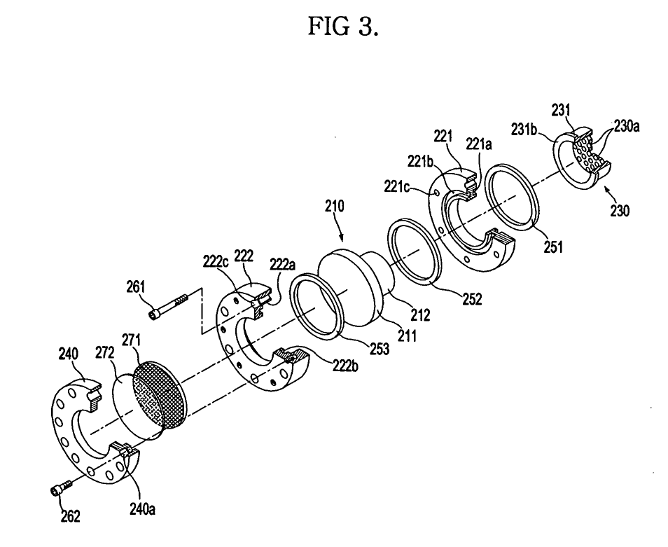

Referring to FIGS. 2 and 3, a penetration hole 100a is formed through the wall of the chamber 100, and has several steps formed on an inner periphery of the penetration hole 100a such that a diameter of the penetrating hole 100a decreases stepwise toward the interior of the chamber 100. The penetration hole 100a includes a transparent window 210 to transmit light emitted from the plasma, a frame 220 to support the transparent window 210, a ground cover 230 to enclose a front side of the transparent window 210 facing the interior of the chamber 100, and an outer cover 240 exposed to an outer portion of the chamber 100.

The transparent window 210 comprises a circular base plate 211 facing an outside of the chamber 100, and an extension 212 extended from the base plate 211 to the interior of the chamber 100, in which the extension 212 has a thickness thicker than that of the base plate 211 and a diameter smaller than that of the base plate 211. The transparent window 210 can be made of quartz. However, the present invention is not limited to quartz, and the transparent window 210 may be made of sapphire or other transparent materials instead of the quartz.

The frame 220 holding the periphery of the base plate 211 of the transparent window 210 comprises an inner frame 221 disposed towards the interior of the chamber 100, and an outer frame 222 disposed towards the outer portion of the chamber 100. The outer frame 222 has a receipt recess 222a formed thereon to receive the base plate 211 of the transparent window 210. Accordingly, the outer frame 222 surrounds a circumferential surface and a rear peripheral surface of the base plate 211, and the inner frame 221 surrounds a front peripheral surface of the base plate 211. A first O-ring 251 is interposed between the inner frame 221 and the wall of the chamber 100 for air-tightness, so that air is prevented from being introduced into the chamber 100 during the process, and the interior of the chamber 100 is prevented from being contaminated by the air while maintaining the inside of the chamber 100 in the vacuum state of the predetermined level within the chamber 100. Additionally, second and third O-rings 252 and 253 are interposed between the inner frame 221 and the base plate 211, and between the outer frame 222 and the base plate 211, respectively. The second and third O-rings 252 and 253 serve not only to maintain air-tightness, but also to prevent the transparent window 210 from being broken due to an excessive impact directly transmitted thereto upon contact of the quartz transparent window 210 to the frame 220. The inner frame 221 and the outer frame 222 have O-ring grooves 221a, 221b, and 222b formed thereon to install the O-rings 251, 252 and 253, respectively. The frame 220 is fixed to the wall of the chamber 100 by a first fixing bolt 261, which is fastened through the outer circumference of the frame 220 to the wall of the chamber 100. For this purpose, screw holes 221c and 222c are formed through the inner frame 221 and the outer frame 222 at corresponding positions thereof, respectively.

The ground cover 230 serves to maintain the ground continuity around the transparent window 210. The ground cover 230 surrounds some portion of the front side of the extension 212 of the transparent window 210 as shown in FIG. 2. The ground cover 230 has a plurality of holes 230a formed therethrough to allow light emitted from the plasma to pass through the ground cover 230. The ground cover 230 has a skirt portion 231 formed at a rear end thereof to extend in a radial direction, and supported by the inner frame 221 and the wall of the chamber 100.

The ground cover 230 is made of aluminum, which is an electrically conductive material. in order to enhance a abrasive resistance, thermal resistance, and the like, aluminum components may have a coated surface formed by an anodizing treatment. An optical guide of a conventional technology as mentioned above has the anodized surface, and the anodized coating on the surface acts as an electrically insulating material. According to this embodiment, however, in order to maintain the ground continuity with the wall of the chamber 100, the skirt portion 231 of the ground cover 230 has opposite sides respectively constituted by bare surfaces 231a and 231b, from which the anodized coating is removed or is not formed, and electrically connected to the wall of the chamber 100 and the inner frame 221. Accordingly, together with the wall of the chamber 100, the ground cover 230 is also in an earth grounded state. At this time, the wall of the chamber 100 and the inner frame 221 may contact the bare surfaces 231a and 231b of the ground cover 230. In this embodiment, only the opposite sides of the skirt portion 231 are constituted by the bare surfaces 231a and 231b, and other portions of the ground cover 230 are formed with the anodized coating 232. However, the present general inventive concept is not limited to this construction, and an entire surface contacting the wall of the chamber 100 may be constituted by the bare surfaces 231a and 231b, if necessary.

The outer cover 240 is disposed on the outside of the outer frame 222. A shielding net 271 made of stainless steel to prevent the RF electric field generated within the chamber 100 from escaping, and an ultraviolet (UV) filter 272 to shield against ultraviolet rays emitted by the plasma are equipped between the outer cover 240 and the outer frame 220. The shielding net 271 and the UV filter 272 are provided to ensure the security of users viewings the interior of the chamber 100. The outer cover 240 has a plurality of screw holes 240a formed through the circumference of the outer cover 240 to fasten a plurality of second fixing bolts 262, which fix the outer cover 240 to the outer frame 220.

In the plasma processing apparatus according to the present general inventive concept, the transparent window 210 disposed in the view port 200 is surrounded by the ground cover 230 electrically contacting the wall of the chamber 100. Accordingly, ground continuity is maintained around the transparent window 210, and uniformity of the electric field and the plasma is ensured within the chamber 100.

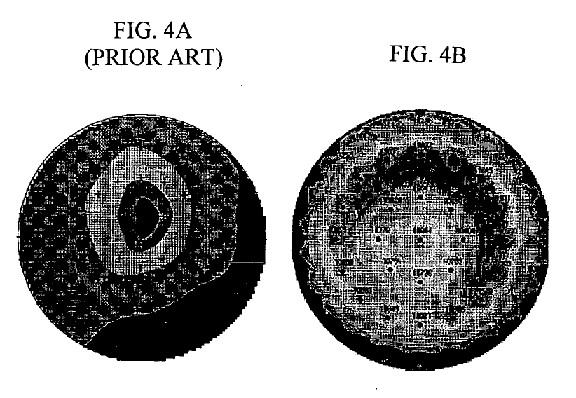

FIGS. 4A and 4B are topographs illustrating distribution of an etch rate on a wafer subjected to an etching process using conventional plasma processing equipment and the plasma processing apparatus according to an embodiment of the present general inventive concept, respectively. In a case of the etching process on the wafer using the conventional plasma processing equipment as shown in FIG. 4A, it can be seen that the distribution of etch rate is asymmetrical on the wafer, whereas, in a case of the etching process on the wafer using the plasma processing apparatus of FIG. 4B, it can be seen that the distribution of etch rate is symmetrical over the entire surface of the wafer.

As apparent from the above description, the plasma processing apparatus according to the present general inventive concept is provided with the ground cover, which can ensure the ground continuity around the view port, thereby providing uniformity of the electric field and the plasma within the chamber. Accordingly, the uniformity of the process and the yield of the wafer are enhanced.

Although a few embodiments of the present general inventive concept have been shown and described, it would be appreciated by those skilled in the art that changes may be made in this embodiment without departing from the principles and spirit of the invention, the scope of which is defined in the claims and their equivalents.

What is claimed is:

1. A plasma processing apparatus, comprising:
an earth-grounded chamber;
a gas supply and an RF power supply to create plasma within the chamber;
a view port formed through a chamber wall to allow observation of an interior of the chamber;
a transparent window disposed in the view port to transmit light created from the plasma therethrough; and
a ground cover disposed in the view port in an earth grounded state to maintain a ground continuity around the transparent window.

2. The apparatus according to claim 1, wherein the ground cover contacts the chamber wall to form a contact surface, and the contact surface is a bare surface.

3. The equipment according to claim 2, wherein the ground cover comprises a plurality of holes formed therethrough to allow the light emitted from the plasma to pass through the ground cover.

4. The apparatus according to claim 3, wherein the ground cover covers a front side of the transparent window facing the interior of the chamber.

5. The apparatus according to claim 1, wherein the view port comprises a frame to fix the transparent window to the chamber.

6. The apparatus according to claim 5, wherein the view port comprises at least one O-ring to maintain air-tightness.

7. The apparatus according to claim 1, wherein the view port comprises:
a shielding net to prevent an RF electric field generated within the chamber from escaping; and
an ultraviolet filter to shield the view port against ultraviolet rays emitted by the plasma.

8. A plasma processing apparatus, comprising:
an earth-grounded chamber having a chamber wall to define an inside, and a penetrating hole formed in the chamber wall;
a gas supply and an RF power supply to create plasma within the inside of the chamber; and
a view port disposed in the penetrating hole of the chamber wall, and having a transparent window to provide observation of a state of the plasma in the inside of the chamber, and a ground cover disposed in the penetrating hole of the chamber wall to provide an earth-grounded state to the penetrating hole of the chamber wall.

9. The apparatus according to claim 8, wherein the earth-grounded chamber is connected to a ground to maintain the earth-grounded state through the chamber wall, the penetrating hole provides a discontinuity of the earth-grounded state, and the ground cover provides the earth-grounded state to the penetrating hole to prevent the discontinuity of the earth-grounded state around the penetrating hole.

10. The apparatus according to claim 8, wherein the view port comprises a frame to attach the transparent window to the chamber wall, and the ground cover comprises a first portion connected to the frame to maintain the earth-grounded state around the view port.

11. The apparatus according to claim 10, wherein the transparent window comprises a first surface facing the inside of the earth-grounded chamber, and a second surface facing an outside of the earth-grounded chamber, and the ground cover comprises a second portion disposed on the first surface of the transparent window and having one or more holes through which the observation of the state of the plasma in the inside of the chamber is provided.

12. The apparatus according to claim 10, wherein the ground cover comprises a second portion disposed on a plane corresponding to the penetrating hole of the chamber wall, and having one or more holes to provide the observation of the state of the plasma in the inside of the earth-grounded chamber.

13. The apparatus according to claim 12, wherein the second portion of the ground cover is coated to define the one or more holes.

14. The apparatus according to claim 12, wherein the first portion of the ground cover is a non-coated portion and the second portion of the ground cover is a coated portion.

15. The apparatus according to claim 8, wherein the chamber wall comprises an inside surface to define the inside, and an outside surface having a thickness with the inside surface, the penetrating hole is formed from the inside surface to the outside surface, and the ground cover covers the penetrating hole corresponding to the inside surface of the chamber wall so that a discontinuity of the earth-grounded state around the penetrating hole is prevented.

16. The apparatus according to claim 15, wherein the ground cover comprises a coated portion to cover the penetrating hole and a non-coated portion to be electrically connected to the frame so that the earth-grounded state is maintained in the penetrating hole.

17. The apparatus according to claim 8, wherein the chamber wall comprises one or more steps to define the penetrating hole, and the view port comprises a frame to attach the transparent to one of the one or more steps of the chamber wall.

18. The apparatus according to claim 8, wherein the ground cover comprises portions electrically connected to the frame and one of the one or more steps.

19. The apparatus according to claim 8, wherein the ground cover comprises a first portion disposed on a surface of the transparent window facing the inside of the earth-grounded chamber and a second portion connected to the frame to maintain the penetrating hole in the earth-grounded state.

20. A plasma processing apparatus, comprising:
an earth-grounded chamber having an inside surface to define an inside thereof, an outside surface to define an outside thereof, and one or more steps to define a penetrating hole formed from the inside surface to the outside surface;
a gas supply and an RF power supply to create plasma within the inside of the chamber; and
a view port disposed in the penetrating hole of the chamber wall, and having a transparent window to provide observation of a state of the plasma in the inside of the chamber, a frame to attach the transparent window to the frame, and a ground cover disposed in the penetrating hole of the chamber wall and having a portion to be electrically connected to the earth-grounded chamber so that an earth-grounded state is provided to the penetrating hole of the chamber wall.
